(19) United States
(12) Patent Application Publication
(10) Pub. No.: US 2024/0315110 A1
(43) Pub. Date: Sep. 19, 2024

(54) DISPLAY DEVICE AND METHOD FOR MANUFACTURING DISPLAY DEVICE

(71) Applicant: SHARP KABUSHIKI KAISHA, Sakai City, Osaka (JP)

(72) Inventors: Kota ADACHI, Sakai City, Osaka (JP); TSUYOSHI KAMADA, Sakai City, Osaka (JP); YASUSHI ASAOKA, Sakai City, Osaka (JP)

(21) Appl. No.: 18/577,362

(22) PCT Filed: Sep. 2, 2021
(86) PCT No.: PCT/JP2021/032212

§ 371 Date: Jan. 8, 2024

(51) Int. Cl. H10K 59/80; H10K 59/12

(52) U.S. Cl. CPC H10K 59/80515; H10K 59/1201

(57) ABSTRACT

A display device includes: a pixel electrode; a counter electrode provided over the pixel electrode; and a functional layer provided between the pixel electrode and the counter electrode. The functional layer has a first portion overlapping an end of the pixel electrode, and a second portion overlapping a middle of the pixel electrode. The first portion is thicker than the second portion.

### TECHNICAL FIELD

The disclosure relates to a display device, and a method for manufacturing the display device.

### BACKGROUND ART

For instance, Patent Literature 1 discloses a display device having the following: a first pixel having a first light-emitting layer overlapping an entire first pixel electrode; and a second pixel being adjacent to the first pixel, and having a second light-emitting layer overlapping an entire second pixel electrode, wherein the second light-emitting layer overlaps the end of the first pixel electrode.

### CITATION LIST

### Patent Literature

Patent Literature 1: International Publication No. WO2020/049738

### SUMMARY

### Technical Problem

However, in Patent Literature 1, the display device is manufactured by, for instance, patterning the second light-emitting layer over the patterned first light-emitting layer; hence, the portion of the second light-emitting layer that is to overlap the end of the first pixel electrode deviates in some cases. Accordingly, the end of the first pixel electrode cannot be covered, causing current concentration at the end of the first pixel electrode, thus possibly deteriorating the display device.

The present disclosure mainly aims to provide a display device and a method for manufacturing the display device that can prevent deterioration.

### Solution to Problem

A display device according to one aspect of the present disclosure includes the following: a pixel electrode; a counter electrode provided over the pixel electrode; and a functional layer provided between the pixel electrode and the counter electrode, wherein the functional layer has a first portion overlapping the end of the pixel electrode, and a second portion overlapping the middle of the pixel electrode, and the first portion is thicker than the second portion.

A method for manufacturing a display device according to one aspect of the present disclosure is a method for manufacturing a display device with a functional layer provided between a pixel electrode and a counter electrode provided over the pixel electrode. The method includes the following steps: a) forming a photosensitive composition layer containing a functional material onto the pixel electrode; and b) subjecting the photosensitive composition layer to exposure and development, to form the functional layer having a first portion that overlaps the end the pixel electrode, and a second portion that overlaps the middle of the pixel electrode, wherein the first portion is thicker than the second portion.

Furthermore, a method for manufacturing a display device according to another aspect of the present disclosure is a method for manufacturing a display device including a plurality of pixel electrodes including a first pixel electrode and a second pixel electrode, a counter electrode provided over the plurality of pixel electrodes, and a light-emitting layer provided between the plurality of pixel electrodes and the counter electrode, and including a first light-emitting layer containing a first light-emitting material and a second light-emitting layer containing a second light-emitting material. The method includes the following steps: a) forming a first photosensitive composition layer containing the first light-emitting material onto the plurality of pixel electrodes, followed by exposure and development, to form a first light-emitting layer including a first first-light-emitting-layer portion that overlaps the end of the first pixel electrode, and a first second-light-emitting-layer portion that overlaps the middle of the first pixel electrode; and b) forming a second photosensitive composition layer containing the second light-emitting material onto the first light-emitting layer, followed by exposure and development, to form a second light-emitting layer including a second first-light-emitting-layer portion that overlaps the end of the first pixel electrode and the first first-light-emitting-layer portion, and a second second-light-emitting-layer portion that overlaps the middle of the second pixel electrode, wherein a set of the first first-light-emitting-layer portion and the second first-light-emitting-layer portion is thicker than the first second-light-emitting-layer portion.

### BRIEF DESCRIPTION OF DRAWINGS

FIG. 1 schematically illustrates an example stacked structure of a display device according to a first embodiment.

FIG. 2 schematically illustrates an example stacked structure of a display device according to a first modification.

FIG. 3 schematically illustrates an example stacked structure of a display device according to a second modification.

FIG. 4 schematically illustrates an example stacked structure of a display device according to a second embodiment.

FIG. 5A illustrates an example process step in a method for manufacturing the display device according to the second embodiment.

FIG. 5B illustrates an example process step in the method for manufacturing the display device according to the second embodiment.

FIG. 5C illustrates an example process step in the method for manufacturing the display device according to the second embodiment.

FIG. 6 schematically illustrates an example stacked structure of a display device according to a third embodiment.

FIG. 7A illustrates an example process step in a method for manufacturing the display device according to the third embodiment.

FIG. 7B illustrates an example process step in the method for manufacturing the display device according to the third embodiment.

FIG. 7C illustrates an example process step in the method for manufacturing the display device according to the third embodiment.

FIG. 7D illustrates an example process step in the method for manufacturing the display device according to the third embodiment.

### DESCRIPTION OF EMBODIMENTS

Embodiments of the present disclosure will be described with reference to the drawings. It is noted that identical or equivalent components will be denoted by identical signs throughout the drawings, and that the description of redundancies will be omitted. The following embodiments are mere examples of the present disclosure. The present disclosure is not limited to the following embodiments at all.

### First Embodiment

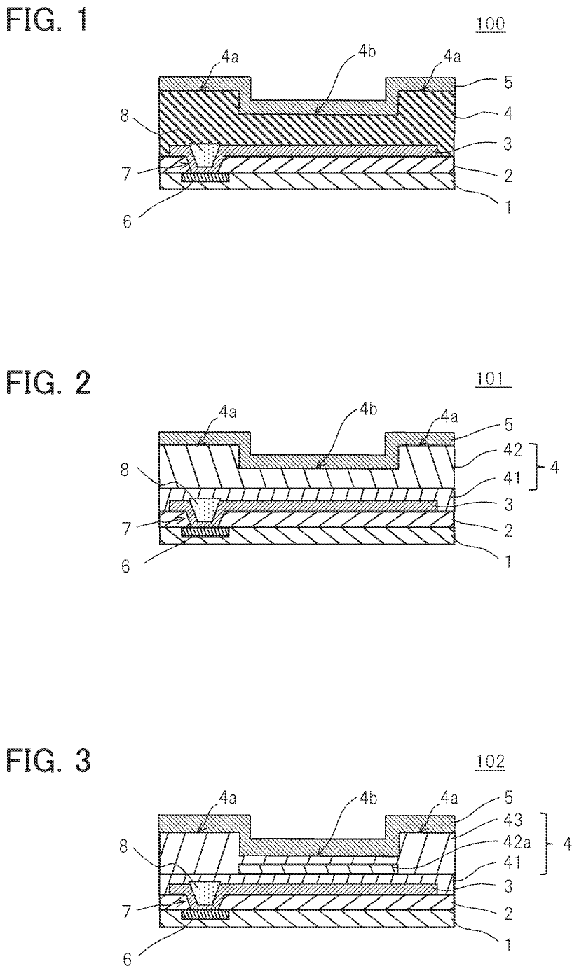

FIG. 1 schematically illustrates an example stacked structure of a display device 100 according to this embodiment.

The display device 100 is a device that emits light. The display device 100 may be, for instance, a lighting device (e.g., a backlight) that emits white light or light of other colors, or a display device that emits light to display an image (including, but not limited to, character information). This embodiment describes an instance where the display device 100 includes a single light-emitting element constituting a single pixel in the display device. The display device can be formed by, for instance, arranging a plurality of pixels in matrix.

As illustrated in FIG. 1, the display device 100 has, for instance, a structure in which an insulating layer 2, a pixel electrode 3, an intermediate layer 4, and a counter electrode 5 are stacked sequentially on the substrate 1. FIG. 1 illustrates a single pixel (corresponding to a single light-emitting element); the display device 100 includes at least one light-emitting element.

The substrate 1 is made of glass for instance and functions as a support that supports each of the foregoing layers. Switching elements 6, such as thin-film transistors (TFTs), for instance, are provided on the substrate 1.

The insulating layer 2 is provided on the substrate 1 and flattens the upper surface of the substrate 1 provided with the switching elements 6. Contact holes 7 are provided in the insulating layer 2. It is noted that the substrate 1 with the switching elements 6 and insulating layer 2 formed thereon can be referred to as an array substrate.

The pixel electrode 3 is provided on the insulating layer 2. The pixel electrode 3 is connected to the switching elements 6 via the contact holes 7. That is, the pixel electrode 3 is provided in the contact holes 7. Furthermore, it is preferable that an insulator 8 be provided on the pixel electrode 3 provided in the contact holes 7. In other words, the contact holes 7 are filled with the insulator 8, thus constituting insulating portions. The insulator 8 flattens the surface with the pixel electrode 3 formed, thus enabling each layer, the intermediate layer 4 in particular, formed on the pixel electrode 3 to be flatter. Furthermore, the insulator 8 can prevent current concentration near the contact holes 7.

The counter electrode 5 is provided over the pixel electrode 3. The counter electrode 5 faces the pixel electrode 3.

The pixel electrode 3 and the counter electrode 5 are composed of, for instance, a conductive material, such as metal or transparent conductive oxide. Examples of the metal include Al, Cu, Au, and Ag. Examples of the transparent conductive oxide include indium tin oxide (ITO), indium zinc oxide (IZO), zinc oxide (ZnO), aluminum zinc oxide (ZnO:Al (AZO)), and boron zinc oxide (ZnO:B (BZO)). It is noted that the pixel electrode 3 and the counter electrode 5 may be, for instance, a stack including at least one metal layer and/or at least one transparent conductive oxide layer.

The counter electrode 5 can be made of a light-transparent material for instance. A usable example of the light-transparent material is a transparent conductive material. To be specific, usable examples of the light-transparent material include indium tin oxide (ITO), indium zinc oxide (IZO), tin oxide (SnO₂), and fluorine-doped tin oxide (FTO). These materials, which have high transmittance of visible light, improve the light emission efficiency of a light-emitting element.

The pixel electrode 3 can be made of a light-reflective material for instance. A usable example of the light-reflective material is a metal material. To be specific, usable examples of the light-reflective material include aluminum (Al), silver (Ag), copper (Cu), and gold (Au). These materials, which have high reflectance of visible light, improve the light emission efficiency.

The intermediate layer 4 is provided between the pixel electrode 3 and the counter electrode 5. The intermediate layer 4 includes at least one functional layer. The intermediate layer 4 in the display device 100 is composed of a single functional layer, and the functional layer is a light-emitting layer. The functional layer is formed in a region including at least a part of an emission region. The light-emitting layer emits light in response to a first electric charge supplied from the pixel electrode 3, and to a second electric charge supplied from the counter electrode 5. Accordingly, the light-emitting element emits light. It is noted that the second electric charge has a polarity opposite to that of the first electric charge.

The at least one functional layer included in the intermediate layer 4 includes a first portion 4a and a second portion 4b. The first portion 4a is thicker than the second portion 4b.

The first portion 4a is provided, for instance, over the end of the pixel electrode 3. That is, the first portion 4a overlaps the end of the pixel electrode 3 in plan view. The first portion 4a is also provided so as to cover the end of the pixel electrode 3.

The second portion 4b is provided, for instance, over the middle of the pixel electrode 3. That is, the second portion 4b overlaps the middle of the pixel electrode 3 in plan view.

When the light-emitting element emits light, the second portion 4b is an emission region, and the first portion 4a is a non-emission region or a region that is not intended for light emission. The first portion 4a, which is thick and is less likely to receive electric charges from the pixel electrode 3 and counter electrode 5, constitutes a non-emission region. The first portion 4a is thicker than the second portion 4b, as earlier described, and thus, current concentration at the end of the pixel electrode 3 can be prevented. Furthermore, the pixel electrode 3, which has an end covered with the first portion 4a, is insusceptible to separation. This can prevent deterioration at the end of the pixel electrode 3, and thus, the light-emitting element can be prevented from reduction in its emission area, and luminance degradation.

Furthermore, the first portion 4a preferably overlaps the contact hole 7 and the insulator 8. This can prevent current concentration near the contact hole 7.

Here, reference is made to an instance where the functional layer is a light-emitting layer.

The light-emitting layer contain a light-emitting material. An example of the light-emitting material is a quantum dot. The quantum dot is a semiconductor fine particle having a particle size of 100 nm or smaller and can have a group II-VI semiconductor compound, such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, or HgTe, and/or a crystal of a group III-V semiconductor compound, such as GaAs, GaP, InN, InAs, InP, or InSb, and/or a crystal of a group IV semiconductor compound, such as Si or Ge. Further, the quantum dot may have a core-shell structure where the foregoing semiconductor crystal that is a core is overcoated with a high-bandgap shell material.

The light-emitting layer that is a functional layer can be formed using, for instance, a photosensitive composition containing a light-emitting material. An example of how to form the light-emitting layer that is a functional layer is the following.

The first process step is forming a photosensitive composition layer onto the pixel electrode 3 and insulator 8 by applying and drying a photosensitive composition containing a light-emitting material.

The next is subjecting the photosensitive composition layer to exposure and development, to form a light-emitting layer having a first light-emitting-layer portion that overlaps the end of the pixel electrode 3 corresponding to the first portion 4a, and a second light-emitting-layer portion that overlaps the middle of the pixel electrode corresponding to the second portion 4b.

To be more specific, for instance, the photosensitive composition layer undergoes half-tone exposure where the dose of exposure is adjusted in the portions corresponding to the first portion 4a and second portion 4b, and the photosensitive composition layer undergoes development. When the photosensitive composition is a negative photosensitive composition for instance, the dose of exposure in the portion corresponding to the first portion 4a is set to be larger than the dose of exposure in the portion corresponding to the second portion 4b. Further, when the photosensitive composition is a positive photosensitive composition for instance, the dose of exposure in the portion corresponding to the first portion 4a is set to be smaller than the dose of exposure in the portion corresponding to the second portion 4b. This enables the first portion 4a to be thicker than the second portion 4b.

The intermediate layer 4 is composed of, but not limited to, a single functional layer. The following describes other examples of the intermediate layer 4 on the basis of FIGS. 2 and 3.

### First Modification

FIG. 2 schematically illustrates a stacked structure of a display device 101 according to a first modification.

The display device 101 according to the first modification is an example of the display device 100 according to the first embodiment in which the intermediate layer 4 includes a first charge transport layer 41 and a light-emitting layer 42 as functional layers. The light-emitting layer 42 is similar to the light-emitting layer, which is the functional layer, of the display device 100.

The first charge transport layer 41 is provided between the pixel electrode 3 and the light-emitting layer 42. The first charge transport layer 41 transport the first electric charge from the pixel electrode 3 to the light-emitting layer 42.

The first charge transport layer 41 can be a hole transport layer or an electron transport layer. When, for instance, the pixel electrode 3 is an anode, and the counter electrode 5 is a cathode, the first electric charge is a hole, the second electric charge is an electron, and the first charge transport layer 41 is a hole transport layer. Further, when, for instance, the pixel electrode 3 is a cathode, and the counter electrode 5 is an anode, the first electric charge is an electron, the second electric charge is a hole, and the first charge transport layer 41 is an electron transport layer. For instance, the hole transport layer and the electron transport layer may be a monolayer or a multilayer. When the hole transport layer is a multilayer, an example stacked structure has a layer having a hole injection capability closest to the anode. Further, when the electron transport layer is a multilayer, an example stacked structure has a layer having an electron injection capability closest to the cathode.

Examples of a material that constitutes the hole transport layer include the following: materials containing one or more kinds selected from the group consisting of an oxide, nitride, or carbide containing one or more of Zn, Cr, Ni, Ti, Nb, Al, Si, Mg, Ta, Hf, Zr, Y, La, and Sr; materials, such as 4,4′,4″-tris(9-carbazolyl)triphenylamine (TCTA), 4,4′-bis[N-(1-naphthyl)-N-phenyl-amino]-biphenyl (NPB), zinc phthalocyanine (ZnPC), di[4-(N,N-ditolylamino)phenyl]cyclohexane (TAPC), 4,4′-bis(carbazole-9-yl)biphenyl (CBP), 2,3,6,7,10,11-hexacyano-1,4,5,8,9,12-hexaazatriphenylene (HATCN), and MoO₃; and organic hole transport materials, such as poly(N-vinylcarbazole) (PVK), poly(2,7-(9,9-di-n-octylfluorene)-(1,4-phenylene-((4-sec-butylphenyl)imino)-1,4-phenylene (TFB), a poly(triphenylamine) derivative (Poly-TPD), and poly(3,4-ethylenedioxythiophene)/poly(4-styrenesulfonic acid) (PEDOT-PSS). For these hole transport materials, only one kind may be used, or two or more kinds may be appropriately combined together and used.

Usable examples of a material that constitutes the electron transport layer include electron transport materials, such as zinc oxide (e.g., ZnO), titanium oxide (e.g., TiO₂), and strontium titanium oxide (e.g., SrTiO₃). For these electron transport materials, only one kind may be used, or two or more kinds may be appropriately combined together and used.

These materials that constitute the hole transport layer and electron transport layer are selected as appropriate in accordance with the configuration and characteristics of the display device 101.

Further, a plurality of foregoing light-emitting elements may be combined together to constitute a single display device. In so doing, a display device that emits a plurality of colors can be formed by providing the light-emitting layers with different light emission colors.

### Second Modification

FIG. 3 schematically illustrates a stacked structure of a display device 102 according to a second modification.

The display device 102 according to the second modification is an example of the display device 100 according to the first embodiment in which the intermediate layer 4 includes three functional layers: the first charge transport layer 41, a light-emitting layer 42a, and a second charge transport layer 43.

The second charge transport layer 43 is provided between the light-emitting layer 42a and the counter electrode. The second charge transport layer 43 transports the second electric charge from the counter electrode 5 to the light-emitting layer 42a. Furthermore, the second charge transport layer 42 is structured such that a portion corresponding to the first portion 4a is thicker than a portion corresponding to the second portion 4b.

The light-emitting layer 42a is formed of, for instance, a material similar to that of the light-emitting layer 42, but is different in shape from the light-emitting layer 42. The light-emitting layer 42a has substantially the same shape as the second portion 4b of the second charge transport layer 43 in plan view.

The first charge transport layer 41 and the second charge transport layer 43 each can be a hole transport layer or an electron transport layer. When, for instance, the pixel electrode 3 is an anode, and the counter electrode 5 is a cathode, the first electric charge is a hole, the second electric charge is an electron, the first charge transport layer 41 is a hole transport layer, and the second charge transport layer 43 is an electron transport layer. Further, when, for instance, the pixel electrode 3 is a cathode, and the counter electrode 5 is an anode, the first electric charge is an electrons, the second electric charge is a hole, the first charge transport layer 41 is an electron transport layer, and the second charge transport layer is a hole transport layer. The hole transport layer and the electron transport layer may be a monolayer or a multilayer for instance. When the hole transport layer is a multilayer, an example stacked structure has a layer having a hole injection capability closest to the anode. Further, when the electron transport layer is a multilayer, an example stacked structure has a layer having an electron injection capability closest to the cathode.

### Second Embodiment

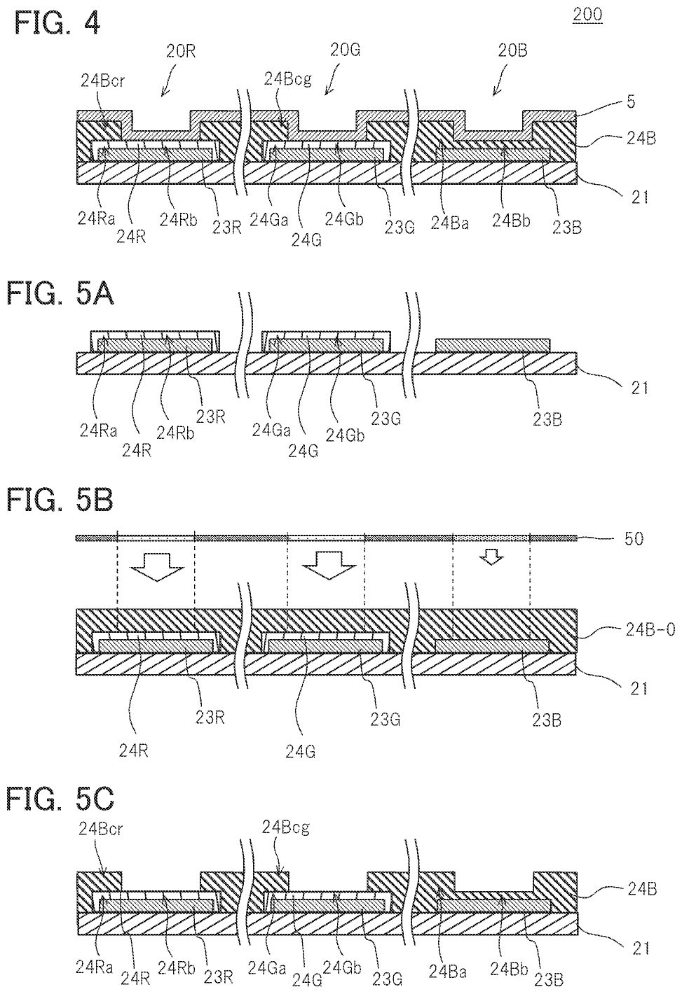

FIG. 4 schematically illustrates an example stacked structure of a display device 200 according to this embodiment.

This embodiment describes an instance where the display device 200 is a single pixel in a display device. The display device can be formed by, for instance, arranging a plurality of pixels in matrix.

As illustrated in FIG. 4, the display device 200 includes the following for instance: a red light-emitting element 20R that emits red light; a green light-emitting element 20G that emits green light; and a blue light-emitting element 20B that emits blue light. The red light-emitting element 20R has a first wavelength as its emission center wavelength and emits light at, for instance, about 630 nm. The green light-emitting element 20G has, as its emission center wavelength, a second wavelength shorter than the first wavelength and emits light at, for instance, about 530 nm. The blue light-emitting element 20B has, as its emission center wavelength, a third wavelength shorter than the second wavelength and emits light at, for instance, about 440 nm.

The red light-emitting element 20R has, for instance, a structure in which a red pixel electrode 23R, a red light-emitting layer 24R, a blue light-emitting-layer portion 24Bcr, and the counter electrode 5 are stacked in the stated order on a substrate 21.

The substrate 21 is made of glass for instance and other things and functions as a support that supports each of the foregoing layers. The substrate 21 may be, for instance, a TFT array substrate with thin-film transistors (TFTs) and other components formed thereon.

The red pixel electrode 23R is disposed on the substrate 21. The red pixel electrode 23R is, for instance, similar to the pixel electrode 3 according to the first embodiment.

The red light-emitting layer 24R is disposed on the red pixel electrode 23R. The red light-emitting layer 24R has a first wavelength as its emission center wavelength and emits light at, for instance, about 630 nm. The red light-emitting layer 24R contains, for instance, a red light-emitting material that has the first wavelength as its emission center wavelength, and that emits light at, for instance, about 630 nm. The red light-emitting material is similar to the light-emitting material according to the first embodiment.

The red light-emitting layer 24R includes a red light-emitting-layer portion 24Ra overlapping the end of the red pixel electrode 23R, and a red light-emitting-layer portion 24Rb overlapping the middle of the red pixel electrode 23R. The red light-emitting-layer portion 24Rb constitutes the emission region of the red light-emitting element 20R.

The blue light-emitting-layer portion 24Bcr is disposed on the red light-emitting layer 24R. To be more specific, the blue light-emitting-layer portion 24Bcr, which is a part of a blue light-emitting layer 24B, is disposed in the red light-emitting element 20R. The blue light-emitting-layer portion 24Bcr overlaps the end of the red pixel electrode 23R, and the red light-emitting-layer portion 24Ra.

In the red light-emitting element 20R, the red light-emitting layer 24R constitutes a functional layer. Moreover, the stack of the blue light-emitting-layer portion 24Bcr is stacked on the end of the red pixel electrode 23R and is thicker than the red light-emitting-layer portion 24Rb. This can prevent current concentration at the end of the red pixel electrode 23R.

Furthermore, the stack of the red light-emitting-layer portion 24Ra and blue light-emitting-layer portion 24Bcr covers the end of the red pixel electrode 23R. Hence, the red pixel electrode 23R is insusceptible to separation. This can prevent deterioration at the end of the red pixel electrode 23R, and thus, the red light-emitting element 20R can be prevented from reduction in its emission area, and luminance degradation.

The counter electrode 5 is disposed on the red light-emitting layer 24R and the blue light-emitting layer 24B. To be more specific, the counter electrode 5 is disposed on the red light-emitting-layer portion 24Rb of the red light-emitting layer 24R, and on the stack of the red light-emitting-layer portion 24Ra and blue light-emitting-layer portion 24Bcr.

The green light-emitting element 20G will be next described.

The green light-emitting element 20G has a configuration similar to that of the red light-emitting element 20R. However, their difference lies in that the red light-emitting layer 24R is replaced with a green light-emitting layer 24G.

The green light-emitting element 20G has, for instance, a structure in which a green pixel electrode 23G, the green light-emitting layer 24G, a blue light-emitting-layer portion 24Bcg, and the counter electrode 5 are stacked in the stated order on the substrate 21.

The green pixel electrode 23G is disposed on the substrate 21. The green pixel electrode 23G is, for instance, similar to the red pixel electrode 23R.

The green light-emitting layer 24G is disposed on the green pixel electrode 23G. The green light-emitting layer 24G has a second wavelength as its emission center wavelength and emits light at, for instance, about 530 nm. The green light-emitting layer 24G contains, for instance, a green light-emitting material that has the second wavelength as its emission center wavelength, and that emits light at, for instance, about 530 nm. The green light-emitting material is similar to the light-emitting material according to the first embodiment.

The green light-emitting layer 24G includes a green light-emitting-layer portion 24Ga overlapping the end of the green pixel electrode 23G, and a green light-emitting-layer portion 24Gb overlapping the middle of the green pixel electrode 23G. The green light-emitting-layer portion 24Gb constitutes the emission region of the green light-emitting element 20G.

The blue light-emitting-layer portion 24Bcg is disposed on the green light-emitting layer 24G. To be more specific, the green light-emitting element 20G is structured such that the blue light-emitting-layer portion 24Bcg is disposed on the green light-emitting-layer portion 24Ga. The blue light-emitting-layer portion 24Bcg overlaps the end of the green pixel electrode 23G, and the green light-emitting-layer portion 24Ga.

In the green light-emitting element 20G, the green light-emitting layer 24G and blue light-emitting-layer portion 24Bcg constitute a functional layer. Moreover, the stack of the green light-emitting-layer portion 24Ga and blue light-emitting-layer portion 24Bcg in the functional layer is stacked on the end of the green pixel electrode 23G and is thicker than the green light-emitting-layer portion 24Gb. This can prevent current concentration at the end of the green pixel electrode 23G of the green light-emitting element 20G.

Furthermore, the stack of the green light-emitting-layer portion 24Ga and blue light-emitting-layer portion 24Bcg covers the end of the green pixel electrode 23G. Hence, the green pixel electrode 23G is insusceptible to separation. This can prevent deterioration at the end of the green pixel electrode 23G, and thus, the green light-emitting element 20G can be prevented from reduction in its emission area, and luminance degradation.

The counter electrode 5 is disposed on the green light-emitting layer 24G and the blue light-emitting layer 24B. To be more specific, the counter electrode 5 is disposed on the green light-emitting-layer portion 24Gb of the green light-emitting layer 24G, and on the blue light-emitting-layer portion 24Bcg of the blue light-emitting layer 24B disposed on the green light-emitting-layer portion 24Ga.

The blue light-emitting element 20B will be next described.

The blue light-emitting element 20B has a configuration similar to that of the red light-emitting element 20R. However, their difference lies in that the red light-emitting layer 24R is replaced with the blue light-emitting layer 24B.

The blue light-emitting element 20B has, for instance, a structure in which a blue pixel electrode 23B, the blue light-emitting layer 24B, and the counter electrode 5 are stacked in the stated order on the substrate 21.

The blue pixel electrode 23B is disposed on the substrate 21. The blue pixel electrode 23B is, for instance, similar to the red pixel electrode 23R.

The blue light-emitting layer 24B is disposed on the blue pixel electrode 23B. The blue light-emitting layer 24B has the third wavelength as its emission center wavelength and emits light at, for instance, about 440 nm. The blue light-emitting layer 24B contains, for instance, a blue light-emitting material that has the third wavelength as its emission center wavelength, and that emits light at, for instance, about 440 nm. The blue light-emitting material is similar to the light-emitting material according to the first embodiment.

The blue light-emitting layer 24B includes a blue light-emitting-layer portion 24Ba overlapping the end of the blue pixel electrode 23B, a blue light-emitting-layer portion 24Bb overlapping the middle of the blue pixel electrode 23B, the blue light-emitting-layer portion 24Bcr overlapping the end of the red pixel electrode 23R, and the blue light-emitting-layer portion 24Bcg overlapping the end of the green pixel electrode 23G. The blue light-emitting-layer portion 24Bb constitutes the emission region of the blue light-emitting element 20B.

In the blue light-emitting element 20B, the blue light-emitting layer 24B constitutes a functional layer. Moreover, the blue light-emitting-layer portion 24Ba in the functional layer is thicker than the blue light-emitting-layer portion 24Bb. This can prevent current concentration at the end of the blue pixel electrode 23B of the blue light-emitting element 20B.

Furthermore, the blue light-emitting-layer portion 24Ba covers the end of the blue pixel electrode 23B, and hence, the blue pixel electrode 23B is insusceptible to separation. This can prevent deterioration at the end of the blue pixel electrode 23B, and thus, the blue light-emitting element 20B can be prevented from reduction in its emission area, and luminance degradation.

The counter electrode 5 is disposed on the blue light-emitting layer 24B. To be more specific, the counter electrode 5 is disposed on the green light-emitting-layer portion 24Gb of the green light-emitting layer 24G, and on the blue light-emitting-layer portion 24Bcg of the blue light-emitting layer 24B disposed on the green light-emitting-layer portion 24Ga.

The following describes an example method for manufacturing the display device 200 according to this embodiment with reference to FIG. 4, and FIG. 5A to FIG. 5C.

The first process step is forming the red pixel electrode 23R, the green pixel electrode 23G, and the blue pixel electrode 23B. The red pixel electrode 23R, the green pixel electrode 23G, and the blue pixel electrode 23B can be formed through various methods publicly known, including sputtering and vacuum evaporation for instance.

As illustrated in FIG. 5A, the next is forming the red light-emitting layer 24R onto the red pixel electrode 23R, and the green light-emitting layer 24G onto the green pixel electrode 23G. To be specific, the red light-emitting layer 24R can be formed by, for instance, applying a photosensitive composition containing a red light-emitting material for forming the red light-emitting layer 24R onto the red pixel electrode 23R, followed by exposure and development. The red light-emitting layer 24R includes the red light-emitting-layer portion 24Ra overlapping the end of the red pixel electrode 23R, and the red light-emitting-layer portion 24Rb overlapping the middle of the red pixel electrode 23R.

Likewise, the green light-emitting layer 24G can be formed by applying a photosensitive composition containing a green light-emitting material for forming the green light-emitting layer 24G onto the green pixel electrode 23G, followed by exposure and development. The green light-emitting layer 24G includes the green light-emitting-layer portion 24Ga overlapping the end of the green pixel electrode 23G, and the green light-emitting-layer portion 24Gb overlapping the middle of the green pixel electrode 23G.

As illustrated in FIG. 5B, the next is forming a positive photosensitive blue light-emitting layer 24B-0 onto the red light-emitting layer 24R and the green light-emitting layer 24G.

Then, the formed positive photosensitive blue light-emitting layer 24B-0 undergoes exposure using a half-tone mask 50. To be specific, predetermined portions in the red light-emitting element 20R and green light-emitting element 20G undergo exposure, and a predetermined portion in the blue light-emitting element 20B undergoes half-tone exposure. In this exposure, the predetermined portion in the blue light-emitting element 20B undergoes exposure at a smaller exposure dose than the predetermined portions corresponding to the red light-emitting element 20R and green light-emitting element 20G.

The exposure is followed by development, to form the blue light-emitting layer 24B, as illustrated in FIG. 5C. The blue light-emitting layer 24B has the blue light-emitting-layer portion 24Ba and blue light-emitting-layer portions 24Bcr and 24Bcg, which are unexposed, and the blue light-emitting-layer portion 24Bb, which corresponds to the portion subjected to half-tone exposure.

Accordingly, a stack of the red light-emitting layer 24R and blue light-emitting layer 24B is formed in the red light-emitting element 20R. Moreover, in the red light-emitting element 20R, the stack of the red light-emitting-layer portion 24Ra and blue light-emitting-layer portion 24Bcr is thicker than the red light-emitting-layer portion 24Rb.

In addition, a stack of the green light-emitting layer 24G and blue light-emitting layer 24B is formed in the green light-emitting element 20G. Moreover, in the green light-emitting element 20G, the stack of the green light-emitting-layer portion 24Ga and blue light-emitting-layer portion 24Bcg is thicker than the green light-emitting-layer portion 24Gb.

Furthermore, the blue light-emitting layer 24B, which is a functional layer, having the blue light-emitting-layer portion 24Ba and blue light-emitting-layer portion 24Bb is formed in the blue light-emitting element 20B. As described above, the blue light-emitting-layer portion 24Ba is thicker than the blue light-emitting-layer portion 24Bb.

Since half-tone exposure is performed as described above, the blue light-emitting layer 24B can be formed through single exposure and development. Further, even if the half-tone mask 50 deviates during the half-tone exposure, the area of the exposed region does not change, and hence, the area of the emission region of each light-emitting element can remain unchanged.

The next is forming the counter electrode 5 onto the blue light-emitting layer 24B. The counter electrode 5 can be formed through various methods publicly known, including sputtering and vacuum evaporation for instance. Through these process steps, the display device 200 illustrated in FIG. 4 can be manufactured.

It is noted that although the positive photosensitive blue light-emitting layer 24B-0 is used for forming the blue light-emitting layer 24B in the foregoing, a negative photosensitive blue light-emitting layer may be used. In so doing, portions corresponding to the blue light-emitting-layer portions 24Bcr and 24Bcg need to undergo exposure, and a portion corresponding to the blue light-emitting-layer portion 24Bb needs to undergo half-tone exposure.

### Third Embodiment

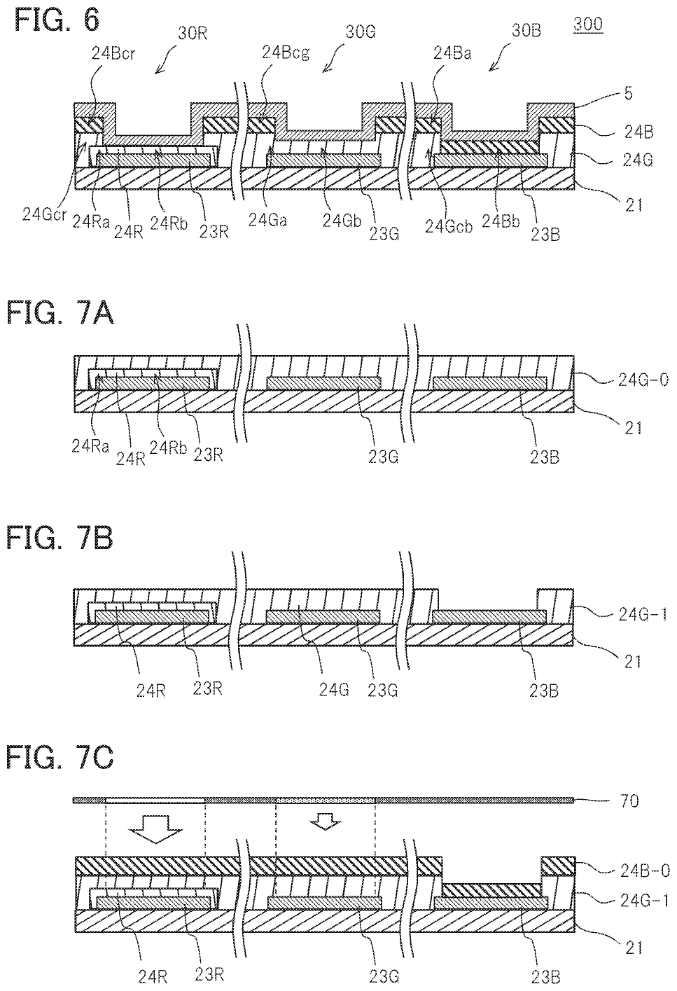

FIG. 6 schematically illustrates an example stacked structure of a display device 300 according to this embodiment.

This embodiment describes an instance where a single light-emitting element constitutes a single pixel in the display device. The display device can be formed by, for instance, arranging a plurality of pixels (a plurality of light-emitting elements) in matrix.

The display device 300 is the display device 200 according to the second embodiment in which the light-emitting elements 20R, 20G, and 20B of the respective colors are replaced with light-emitting elements 30R, 30G, and 30B having different stacked structures.

The red light-emitting element 30R has, for instance, a structure in which the red pixel electrode 23R, the red light-emitting layer 24R, a green light-emitting-layer portion 24Gcr, the blue light-emitting-layer portion 24Bcr, and the counter electrode 5 are stacked in the stated order on the substrate 21.

The red pixel electrode 23R is disposed on the substrate 21.

The red light-emitting layer 24R is disposed on the red pixel electrode 23R. The red light-emitting layer 24R includes the red light-emitting-layer portion 24Ra overlapping the end of the red pixel electrode 23R, and the red light-emitting-layer portion 24Rb overlapping the middle of the red pixel electrode 23R. The red light-emitting-layer portion 24Rb constitutes the emission region of the red light-emitting element 30R.

The green light-emitting-layer portion 24Gcr is disposed on the red light-emitting layer 24R. To be more specific, the green light-emitting-layer portion 24Gcr is a part of the green light-emitting layer 24G and overlaps the red light-emitting-layer portion 24Ra.

The blue light-emitting-layer portion 24Bcr is disposed on the green light-emitting-layer portion 24Gcr and the red light-emitting layer 24R. To be more specific, the blue light-emitting-layer portion 24Bcr is a part of the blue light-emitting layer 24B and overlaps the green light-emitting-layer portion 24Gcr and the red light-emitting-layer portion 24Ra.

In the red light-emitting element 30R, the red light-emitting layer 24R constitutes a functional layer. Moreover, the stack of the red light-emitting-layer portion 24Ra, green light-emitting-layer portion 24Gcr, and blue light-emitting-layer portion 24Bcr is stacked on the end of the red pixel electrode 23R and is thicker than the red light-emitting-layer portion 24Rb. This can prevent current concentration at the end of the red pixel electrode 23R.

Furthermore, the stack of the red light-emitting-layer portion 24Ra, green light-emitting-layer portion 24Gcr, and blue light-emitting-layer portion 24Bcr covers the end of the red pixel electrode 23R. Hence, the red pixel electrode 23R is insusceptible to separation. This can prevent deterioration at the end of the red pixel electrode 23R, and thus, the red light-emitting element 30R can be prevented from reduction in its emission area, and luminance degradation.

The counter electrode 5 is disposed on the red light-emitting layer 24R, the green light-emitting layer 24G, and the blue light-emitting layer 24B. To be more specific, the counter electrode 5 is disposed on the stack of the red light-emitting-layer portion 24Ra, green light-emitting-layer portion 24Gcr, and blue light-emitting-layer portion 24Bcr.

The green light-emitting element 30G will be next described.

The green light-emitting element 30G has, for instance, a structure in which the green pixel electrode 23G, the green light-emitting layer 24G, the blue light-emitting-layer portion 24Bcg, and the counter electrode 5 are stacked in the stated order on the substrate 21.

The green pixel electrode 23G is disposed on the substrate 21.

The green light-emitting layer 24G is disposed on the green pixel electrode 23G. The green light-emitting layer 24G includes the green light-emitting-layer portion 24Ga overlapping the end of the green pixel electrode 23G, and the green light-emitting-layer portion 24Gb overlapping the middle of the green pixel electrode 23G. Further, for instance, the green light-emitting-layer portion 24Ga is thicker than the green light-emitting-layer portion 24Gb. The green light-emitting-layer portion 24Gb constitutes the emission region of the green light-emitting element 30G.

The blue light-emitting-layer portion 24Bcg is disposed on the green light-emitting layer 24G. To be more specific, the blue light-emitting-layer portion 24Bcg is a part of the blue light-emitting layer 24B and is disposed on the green light-emitting-layer portion 24Ga. The blue light-emitting-layer portion 24Bcg overlaps the green light-emitting-layer portion 24Ga.

In the green light-emitting element 30G, the green light-emitting layer 24G constitutes a functional layer. Moreover, the green light-emitting-layer portion 24Ga in the functional layer is thicker than the green light-emitting-layer portion 24Gb. This can prevent current concentration at the end of the green pixel electrode 23G of the green light-emitting element 30G.

Furthermore, the stack of the green light-emitting-layer portion 24Ga and blue light-emitting-layer portion 24Bcg covers the end of the green pixel electrode 23G. Hence, the green pixel electrode 23G is insusceptible to separation, and thus, current concentration at the end of the green pixel electrode 23G can be prevented. This can prevent deterioration at the end of the green pixel electrode 23G, and thus, the green light-emitting element 30G can be prevented from reduction in its emission area, and luminance degradation.

The counter electrode 5 is disposed on the green light-emitting layer 24G and the blue light-emitting layer 24B. To be more specific, the counter electrode 5 is disposed on the green light-emitting-layer portion 24Gb, and the blue light-emitting-layer portion 24Bcg disposed on the green light-emitting-layer portion 24Ga.

The blue light-emitting element 30B will be next described.

The blue light-emitting element 30B has, for instance, a structure in which the blue pixel electrode 23B, a green light-emitting-layer portion 24Gcb, the blue light-emitting layer 24B, and the counter electrode 5 are stacked in the stated order on the substrate 21.

The blue pixel electrode 23B is disposed on the substrate 21.

The green light-emitting-layer portion 24Gcb is disposed on the blue pixel electrode 23B. The green light-emitting-layer portion 24Gcb overlaps the end of the blue pixel electrode 23B.

The blue light-emitting layer 24B is disposed on the green light-emitting-layer portion 24Gcb and the blue pixel electrode 23B. The blue light-emitting layer 24B has the blue light-emitting-layer portion 24Ba and the blue light-emitting-layer portion 24Bb.

The blue light-emitting-layer portion 24Ba is disposed on the green light-emitting-layer portion 24Gcb. The blue light-emitting-layer portion 24Ba overlaps the end of the blue pixel electrode 23B. The blue light-emitting-layer portion 24Bb overlaps the middle of the blue pixel electrode 23B. The blue light-emitting-layer portion 24Bb constitutes the emission region of the blue light-emitting element 30B.

In the blue light-emitting element 30B, the green light-emitting-layer portion 24Gcb and the blue light-emitting layer 24B constitute a functional layer. Moreover, the stack of the green light-emitting-layer portion 24Gcb and blue light-emitting-layer portion 24Ba in the functional layer is thicker than the blue light-emitting-layer portion 24Bb. This can prevent current concentration at the end of the blue pixel electrode 23B of the blue light-emitting element 30B.

Furthermore, the stack of the green light-emitting-layer portion 24Gcb and blue light-emitting-layer portion 24Ba covers the end of the blue pixel electrode 23B. Hence, the blue pixel electrode 23B is insusceptible to separation. This can prevent deterioration at the end of the blue pixel electrode 23B, and thus, the blue light-emitting element 30B can be prevented from reduction in its emission area, and luminance degradation.

The counter electrode 5 is disposed on the blue light-emitting layer 24B. To be more specific, the counter electrode 5 is disposed on the blue light-emitting-layer portion 24Bb of the blue light-emitting layer 24B, and on the stack of the green light-emitting-layer portion 24Gcb and blue light-emitting-layer portion 24Ba.

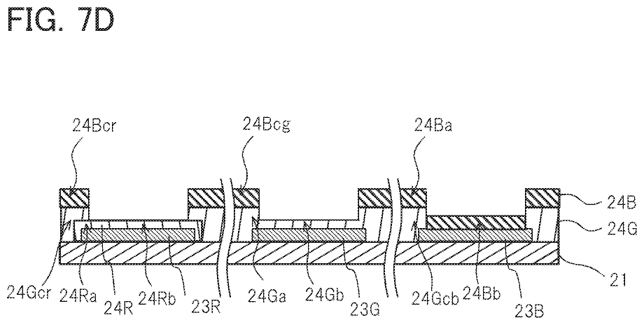

The following describes an example method for manufacturing the display device 300 according to this embodiment with reference to FIG. 6, and FIG. 7A to FIG. 7D.

The first process step is forming the red pixel electrode 23R, the green pixel electrode 23G, and the blue pixel electrode 23B. The red pixel electrode 23R, the green pixel electrode 23G, and the blue pixel electrode 23B can be formed through various methods publicly known, including sputtering and vacuum evaporation for instance.

As illustrated in FIG. 7A, the next is forming the red light-emitting layer 24R onto the red pixel electrode 23R and forming a positive photosensitive green light-emitting layer 24G-0. It is noted that the red light-emitting layer 24R includes the red light-emitting-layer portion 24Ra overlapping the end of the red pixel electrode 23R, and the red light-emitting-layer portion 24Rb overlapping the middle of the red pixel electrode 23R.

As illustrated in FIG. 7B, the next is subjecting a predetermined portion in the positive photosensitive green light-emitting layer 24G-0 in the blue light-emitting element 30B to exposure and development, to form a positive photosensitive green light-emitting layer 24G-1 with the predetermined portion in the blue light-emitting element 30 removed.

As illustrated in FIG. 7C, the next is forming a positive photosensitive blue light-emitting layer 24B-0 onto the positive photosensitive green light-emitting layer 24G-1. Then, the positive photosensitive blue light-emitting layer 24B-0 and the positive photosensitive green light-emitting layer 24G-1 undergo exposure using a half-tone mask 70. To be specific, a predetermined portion in the red light-emitting element 30R undergoes exposure, and a predetermined portion in the green light-emitting element 30G undergoes half-tone exposure. In this exposure, the predetermined portion in the green light-emitting element 30G undergoes exposure at a smaller exposure dose than the predetermined portion in the red light-emitting element 30R. It is noted that the predetermined portion in the green light-emitting element 30G undergoes exposure dose adjustment to such a degree that the positive photosensitive blue light-emitting layer 24B-0 is removed. It is furthermore noted that the predetermined portion in the green light-emitting element 30G undergoes exposure dose adjustment to such a degree that the positive photosensitive green light-emitting layer 24G-1 is partly removed.

The exposure is followed by development, to form the blue light-emitting layer 24B and the green light-emitting layer 24G, as illustrated in FIG. 7D. The blue light-emitting layer 24B includes the blue light-emitting-layer portion 24Ba, which is unexposed, and the blue light-emitting-layer portions 24Bcr and 24Bcg. Further, the green light-emitting layer 24G includes the green light-emitting-layer portions 24Ga and 24Gcr, which are unexposed, and the green light-emitting-layer portion 24Gb, which has undergone half-tone exposure. The green light-emitting-layer portions 24Ga and 24Gcr are thicker than the green light-emitting-layer portion 24Gb.

Accordingly, a stack of the red light-emitting layer 24R, green light-emitting-layer portion 24Gcr, and blue light-emitting-layer portion 24Bcr is formed in the red light-emitting element 30R. Moreover, in the red light-emitting element 30R, the stack of the red light-emitting-layer portion 24Ra, green light-emitting-layer portion 24Gcr, and blue light-emitting-layer portion 24Bcr overlaps the end of the red pixel electrode 23R. Moreover, the green light-emitting-layer portion 24Gcr and the blue light-emitting-layer portion 24Bcr are formed through single exposure and development, as described above, thus enabling the end surfaces of the green light-emitting-layer portion 24Gcr and blue light-emitting-layer portion 24Bcr to be flush with each other, and enabling areas that are to be removed, to be equal to each other. Thus, the areas of the emission regions of individual pixels can be easily maintained equally when a plurality of pixels are formed simultaneously, thus enabling yield improvement at the time of manufacturing the display device.

Further, the green light-emitting layer 24G, which is a functional layer, is formed in the green light-emitting element 30G. Moreover, in the green light-emitting element 30G, the stack of the green light-emitting-layer portion 24Gcb and blue light-emitting-layer portion 24Bcg overlaps the end of the green pixel electrode 23G. Moreover, the green light-emitting-layer portion 24Ga and the blue light-emitting-layer portion 24Bcg are formed through single exposure and development, as described above, thus enabling the end surfaces of the green light-emitting-layer portion 24Ga and blue light-emitting-layer portion 24Bcg to be flush with each other, and enabling areas that are to be removed, to be equal to each other. Thus, the areas of the emission regions of individual pixels can be easily maintained equally when a plurality of pixels are formed simultaneously, thus enabling yield improvement at the time of manufacturing the display device.

Furthermore, a stack of the green light-emitting layer 24G and blue light-emitting layer 24B is formed in the blue light-emitting element 30B. Moreover, in the blue light-emitting element 30B, the stack of the green light-emitting-layer portion 24Gcb and blue light-emitting-layer portion 24Ba overlaps the end of the blue pixel electrode 23B. As described above, the blue light-emitting element 30B can be produced easily by only forming the green light-emitting-layer portion 24Gcb, followed by the blue light-emitting layer 24B.

The next is forming the counter electrode 5 onto the blue light-emitting layer 24B. The counter electrode 5 can be formed through various methods publicly known, including sputtering and vacuum evaporation for instance. Through these process steps, the display device 300 illustrated in FIG. 6 can be manufactured.

The present disclosure is not limited to the foregoing embodiments. Replacement may be performed with substantially the same configuration as the configurations described in these embodiments, with a configuration that exhibits the same action and effect as the same, or with a configuration that can achieve the same object as the same.

For instance, although the second and third embodiments have described an instance where at least one light-emitting element included in the display device is configured such that the light-emitting layer that is a functional layer has a first portion overlapping the end of the pixel electrode, and a second portion overlapping the middle of the pixel electrode, and such that the first portion is thicker than the second portion, instead of or together with the light-emitting layer, a charge transport layer is formed as a functional layer in such a manner that the first portion is thicker than the second portion. The functional layer, when being a light-emitting layer, contains a light-emitting material as a functional material for exerting the function of the functional layer, and the functional layer, when being a charge transport layer, contains a charge transport material as a functional material.

Further, the functional layer in the foregoing embodiments undergoes half-tone exposure, forming the first portion and the second portion thicker than the first portion; the layers other than the functional layer may be formed through various publicly known methods, including a liftoff method, and a liftoff method using a liquid-repellent resist. In the third embodiment for instance, the blue light-emitting layer 24B, when formed in red and green pixels through liftoff, does not have to contain a photosensitive material.

Furthermore, although the foregoing embodiments have described an instance where a red light-emitting element, a green light-emitting element, and a blue light-emitting element are formed in this order, the order of forming the light-emitting elements is not limited to this order. For instance, the red light-emitting layer may be formed after the blue light-emitting layer is formed, and the red light-emitting layer may be formed over the blue light-emitting layer. Further, the foregoing embodiments have described an instance where the wavelength of a firstly formed light-emitting layer is defined as the first wavelength, the wavelength of a secondly formed light-emitting layer is defined as the second wavelength, and the wavelength of a thirdly formed light-emitting layer is defined as the third wavelength, and where the first wavelength is the longest, followed by the second wavelength, followed by the third wavelength; for a change in the order of forming the light-emitting layers, the order of length of the first wavelength, second wavelength, and third wavelength is changed as well accordingly.

1. A display device comprising:
a pixel electrode;
a counter electrode provided over the pixel electrode; and
a functional layer provided between the pixel electrode and the counter electrode,
wherein the functional layer has a first portion overlapping an end of the pixel electrode, and a second portion overlapping a middle of the pixel electrode, and
the first portion is thicker than the second portion.

2. The display device according to claim 1, wherein the first portion covers the end of the pixel electrode.

3. The display device according to claim 1, wherein
the functional layer is a light-emitting layer,
the light-emitting layer has a first light-emitting-layer portion corresponding to the first portion and overlapping the end of the pixel electrode, and a second light-emitting-layer portion corresponding to the second portion and overlapping the middle of the pixel electrode, and
the first light-emitting-layer portion is thicker than the second light-emitting-layer portion.

4. The display device according to claim 3, wherein
the light-emitting layer includes a first light-emitting layer containing a first light-emitting material configured to emit light at a first wavelength that is an emission center wavelength, and a second light-emitting layer containing a second light-emitting material configured to emit light a second wavelength that is an emission center wavelength,
the pixel electrode includes a first pixel electrode and a second pixel electrode,
the first light-emitting layer includes a first first-light-emitting-layer portion overlapping an end of the first pixel electrode, and a first second-light-emitting-layer portion overlapping a middle of the first pixel electrode,
the first light-emitting-layer portion includes the first first-light-emitting-layer portion, and a second first-light-emitting-layer portion overlapping, in the second light-emitting layer, the end of the first pixel electrode, and
the first light-emitting-layer portion is thicker than the first second-light-emitting-layer portion.

5. The display device according to claim 4, wherein
the second light-emitting layer includes the second first-light-emitting-layer portion, a second second-light-emitting-layer portion overlapping a middle of the second pixel electrode, and a third first-light-emitting-layer portion overlapping an end of the second pixel electrode, and
the third first-light-emitting-layer portion is thicker than the second second-light-emitting-layer portion.

6. The display device according to claim 4, wherein the second wavelength is shorter than the first wavelength.

7. The display device according to claim 1, wherein
the functional layer includes a charge transport layer provided over the light-emitting layer,
the charge transport layer has a first charge-transport-layer portion corresponding to the first portion and overlapping the end of the pixel electrode, and a second charge-transport-layer portion corresponding to the second portion and overlapping the middle of the pixel electrode, and
the first charge-transport-layer portion is thicker than the second charge-transport-layer portion.

8. The display device according to claim 1, further comprising an insulating layer provided under the pixel electrode,
wherein the pixel electrode is connected to a switching element via a contact hole provided in the insulating layer, the switching element being provided under the insulating layer, and
the first portion extends to a region where the contact hole is formed.

9. The display device according to claim 8, comprising an insulating portion filled in the contact hole.

10. A method for manufacturing a display device with a functional layer provided between a pixel electrode and a counter electrode provided over the pixel electrode, the method comprising the steps of:
a) forming a photosensitive composition layer containing a functional material onto a pixel electrode; and
b) subjecting the photosensitive composition layer to exposure and development, to form the functional layer having a first portion that overlaps an end the pixel electrode, and a second portion that overlaps a middle of the pixel electrode,
wherein the first portion is thicker than the second portion.

11. A method for manufacturing a display device including a plurality of pixel electrodes including a first pixel electrode and a second pixel electrode, a counter electrode provided over the plurality of pixel electrodes, and a light-emitting layer provided between the plurality of pixel electrodes and the counter electrode, and including a first light-emitting layer containing a first light-emitting material and a second light-emitting layer containing a second light-emitting material, the method comprising the steps of:
a) forming a first photosensitive composition layer containing the first light-emitting material onto the plurality of pixel electrodes, followed by exposure and development, to form a first light-emitting layer including a first first-light-emitting-layer portion that overlaps an end of the first pixel electrode, and a first second-light-emitting-layer portion that overlaps a middle of the first pixel electrode; and
b) forming a second photosensitive composition layer containing the second light-emitting material onto the first light-emitting layer, followed by exposure and development, to form a second light-emitting layer including a second first-light-emitting-layer portion that overlaps the end of the first pixel electrode and the first first-light-emitting-layer portion, and a second second-light-emitting-layer portion that overlaps a middle of the second pixel electrode,
wherein a set of the first first-light-emitting-layer portion and the second first-light-emitting-layer portion is thicker than the first second-light-emitting-layer portion.

12. The method for manufacturing the display device according to claim 11, wherein
step b) includes subjecting the second photosensitive composition layer to exposure and development, to simultaneously form a third first-light-emitting-layer portion that overlaps an end of the second pixel electrode, and
the third first-light-emitting-layer portion is thicker than the second second-light-emitting-layer portion.
